(19) United States
(12) Patent Application Publication
(10) Pub. No.: US 2026/0090230 A1
(43) Pub. Date: Mar. 26, 2026

(54) TRANSPARENT DISPLAY WITH LENSLESS IMAGING CAPABILITY AND IMAGING SYSTEM

(71) Applicant: ams International AG, Jona (CH)

(72) Inventors: Francesco Paolo D’ALEO, Samstagern (CH); Emrah BOSTAN, Martigny-Croix (CH)

(21) Appl. No.: 18/868,662

(22) PCT Filed: May 22, 2023
(86) PCT No.: PCT/EP2023/063625

§ 371 Date: Nov. 22, 2024

(30) Foreign Application Priority Data
May 25, 2022 (DE) 10 2022 113 231.5

(51) Int. Cl. H10K 59/65; G02B 27/01; G02F 1/1362; H04N 23/56; H04N 23/63; H04N 25/20; H10F 39/18; H10H 29/80; H10K 39/34

(52) U.S. Cl. CPC H10K 59/65; G02B 27/0101; G02F 1/1362; H04N 23/56; H04N 23/63; H04N 25/20; H10F 39/184; H10H 29/872; H10K 39/34; G02B 2027/0138

(57) ABSTRACT

A transparent display with lensless imaging capability includes display pixels configured to generate a display image, light emitters configured to illuminate a scene or an object with electromagnetic radiation outside the visible domain, photosensitive elements configured to capture electromagnetic radiation received from the scene or the object and to generate photo signals depending on the captured electromagnetic radiation, and an optical modulator configured to transmit electromagnetic radiation in the visible domain, and to modulate electromagnetic radiation within the illumination wavelength range. The display is substantially transparent in the visible domain.

This disclosure relates to a transparent display with lensless imaging capability, an imaging system comprising such a display, and to a method of manufacturing a transparent display with lensless imaging capability.

Transparent, or see-through, displays is a type of electronic display that allows a user to view contents displayed on a screen of the display while at the same time still being able to also see a scene or an object that is located behind the screen from the user's point of view. Such displays are commonly employed in applications such as head-up displays, particularly in the automotive field, as well as augmented reality systems such as smart glasses. In general, transparent displays embed pixels of an active matrix of the display in the field of view in a distributed manner such that visible light can pass through gaps in between the pixels in order for the display to appear transparent to the user.

The aforementioned applications of heads-up displays and augmented reality devices in addition require some form of imaging, as typically information is to be displayed on the screen that relates to an object or a scene that is in the field of view of the user behind the display. For example, a heads-up display indicates a speed limit, information detected from road signs or navigation instructions. To this end, state-of-the-art approaches typically rely on projection systems, which are bulky and intrinsically do not allow for interactions. Embedded cameras, on the other hand, do not allow for often desirable flat form factors and in addition introduce notches and dark spots on the display as they are not transparent.

Thus, an object to be achieved is to provide a transparent display with lensless imaging capability that overcomes the limitations of existing solutions. A further object is to provide a transparent imaging system comprising such a transparent display, and a method of manufacturing such a transparent display.

These objects are achieved with the subject-matter of the independent claims. Further developments and embodiments are described in dependent claims.

This disclosure overcomes the abovementioned limitations of modern day devices by embedding a transparent camera within a transparent display. Specifically, the improved concept is based on the idea of using one or more transparent substrates and materials, with the transparency spanning at least across the visible range of the electromagnetic spectrum. On these substrates the display pixels, illuminators, the image sensor and lensless optics are embedded in a distributed manner such that both displaying and imaging capability is ensured while keeping the arrangement appear transparent to a user.

In an embodiment, a transparent display with lensless imaging capability comprises a plurality of display pixels that are arranged on a display substrate. The plurality of display pixels is configured to generate a display image in the visible domain of the electromagnetic spectrum. The transparent display further comprises a plurality of light emitters configured to illuminate a scene or an object with electromagnetic radiation within an illumination wavelength range that is outside the visible domain, and a plurality of photosensitive elements configured to capture electromagnetic radiation received from the scene or the object within the illumination wavelength range and to generate photo signals depending on the captured electromagnetic radiation. The transparent display further comprises an optical modulator that is arranged on an incident side of the plurality of photosensitive elements and configured to transmit electromagnetic radiation in the visible domain, and to modulate electromagnetic radiation within the illumination wavelength range. Therein, the display is substantially transparent in the visible domain.

The display pixels are formed from visible light emitters that are configured to emit light in the visible domain of the electromagnetic spectrum, i.e. at optical wavelengths ranging from 400 to 750 nm. For example, the display pixels are formed from RGB light-emitting diodes and are arranged in a two-dimensional matrix for forming a screen for displaying content. Therein, the light emitters of the pixels can be controlled to output a certain respective color, or each pixel is formed by red, green and blue subpixels, for instance. The pixels can be connected to a controller that controls an image to be displayed on the screen formed by the pixels. The display pixels are arranged on a transparent substrate, e.g. a glass or thin film substrate, or a transparent foil. Here and throughout the disclosure, the term “transparent” refers to the visible portion of the electromagnetic spectrum, i.e. light of wavelengths, at which the human eye is sensitive at.

The illuminating light emitters are configured to emit light at an optical illumination wavelength that is outside the visible spectrum, e.g. light in the NIR domain in the range of 750 nm and 1.4 μm or in the SWIR domain in the range of 1.4 μm and 3 μm. The illuminating light emitters can be arranged on the same substrate as the visible light emitters forming the display. For example, the display is formed from a matrix of pixels, wherein each pixel incorporates subpixels that include the aforementioned visible subpixels formed from red, green and blue subpixels as well as the illumination subpixel formed from a light emitter in the NIR or SWIR domain. Alternatively, only some of the pixels can incorporate an illumination light emitter, e.g. the pixels along the periphery of the display. Yet alternatively, the illumination light emitters can be arranged independently from the display pixels, e.g. forming a frame around the display or being arranged on a further transparent substrate.

The photosensitive elements are configured to capture the electromagnetic radiation emitted by the light emitters and reflected off the scene or the object. Thus, the photosensitive elements possess a sensitivity within the illumination wavelength range. For example, the photosensitive elements can be silicon-based photodiodes if the illuminating light emitters emit light at an optical wavelength in the NIR domain, e.g. at 840 or 930 nm. The photosensitive elements further each generate a photo signal depending on the captured electromagnetic radiation by the respective element. The photosensitive elements form an image sensor and can be arranged on the same substrate as the visible light emitters and/or the illumination light emitters. For example, the display is formed from a matrix of pixels, wherein each pixel incorporates subpixels that include the aforementioned visible subpixels formed from red, green and blue subpixels as well as an optional illumination subpixel and a photosensitive element, e.g. a photodiode. Alternatively, only some of the pixels can incorporate a photosensitive element, e.g. the pixels arranged in a center section of the display. Yet alternatively, the photosensitive elements can be arranged independently from the display pixels and the illumination emitters, e.g. in between pixels, or they can be arranged on a further transparent substrate.

The optical modulator is arranged between the object or scene and the image sensor formed from the photosensitive elements. Different from conventional imaging using optical lenses, in which each pixel of an image sensor captures light from a distinct region of an object or scene to be imaged, employing an optical modulator, and hence realizing lensless imaging, results in an encoding of the object or scene information, e.g. by having a different system response for each pixel of image sensor. Therein, each pixel of the image sensor can be understood as capturing an effective weighted sum of system response functions from each point of the object or the scene. A computational inverse algorithm can be employed on the photo signals for reconstructing the image. The optical modulator can be illumination-modulated, mask-modulated, or be realized as a programmable-modulator system. The optical modulator can be arranged on a separate transparent substrate that is arranged adjacent to a substrate comprising the photosensitive elements. Specifically, the optical modulator is configured to be transmissive for visible light, i.e. the optical modulator does not encode optical wavelengths in the visible domain, and to encode light at the illumination wavelength range, e.g. in the NIR or SWIR domain.

The aforementioned elements are arranged such that the display is substantially transparent in the visible domain. This means that a user looking at the display is still able to discern objects or a scene that is arranged behind the display from the user's point of view. An object appears substantially transparent if 70% of optical power in the visible domain is transmitted through said object. Hence, the display pixels, illuminating light emitters and photosensitive elements, which themselves are typically not transparent, can be arranged in a distributed manner, i.e. with gaps in between, in order to ensure that a total of at least 70% of visible light is transmitted through the display.

In an embodiment, the illumination wavelength range is in the near-infrared, NIR, domain. For example, the illumination wavelength range is a range around 840 and/or 930 nm. This wavelength range is invisible to the human eye such that an illumination of a scene or object does not affect its appearance to the user. In addition, in this wavelength range well-established technologies for light emitters and photosensitive elements can be employed for an efficient and cost-effective manufacturing and operation of the display. For example, the photosensitive elements are silicon photodiodes which show sensitivities in the visible domain as well as in the NIR domain up to about 1100 nm. In order to limit a sensitivity of the photosensitive elements to the illumination wavelength range, the photosensitive elements can comprise optical filter elements for blocking visible light, for instance.

In an embodiment, the light emitters are OLEDs, micro-LEDs or vertical-cavity surface-emitting lasers, VCSELs. The light emitters for illuminating the scene or object can be selected from various existing technologies such as organic LEDs, or micro LEDs. For example, the illuminating light emitters are of a same type as the visible light emitters forming the display such that they can be easily manufactured on the same substrate following the same or a similar manufacturing process. Alternatively, the illuminating light emitters can be of a different type, e.g. the display pixels are formed from OLEDs and the illuminating light emitters are formed from micro LEDs or vice versa. This way, they can be manufactured separately on different substrates, for instance, in order to tailor the display technology and the illumination to a specific application. Moreover, in terms of a requirement of an illumination with coherent light or with a higher range, the illuminating light emitters can be formed from VCSELs, likewise arranged on the same substrate as the display pixels or on a different substrate.

Micro-LEDs (light emitting diode, short: LED) are semiconductor light emitting diodes with a particularly small size. For example, a growth substrate for an epitaxial growth of a semiconductor layer sequence of the Micro-LED is removed from the Micro-LED. In other words, the Micro-LED does not comprise the growth substrate. For example, a thickness or height of the Micro-LED in a growth direction of the semiconductor layer sequence is between 1.5 μm and 10 μm.

A light emission surface of the Micro-LED can be rectangular or can have a different shape, for example. In particular, each lateral extension of the light emission surface is at most 100 μm or at most 70 μm in plan view of layers of the semiconductor layer sequence. For example, if the Micro-LED has a rectangular shape, an edge length of the Micro-LED—in particular in plan view of layers of the semiconductor layer sequence—is at most 70 μm or at most 50 μm.

For example, Micro-LEDs are provided on wafers with detachable holding structures, such that the Micro-LED can be detached from the wafer non-destructively. Micro-LEDs may also be referred to as μLEDs, μ-LEDs, uLEDs, u-LEDs, or Micro Light Emitting Diodes.

In an embodiment, the plurality of light emitters is arranged on the display substrate. Arranging the illuminating light emitters alongside the display pixels on a common substrate results in a compact system by minimizing the layers of the finalized display. For example, each or some of the display pixels comprise visible subpixels, e.g. formed by RGB LEDs, and an illuminating light emitter, e.g. a NIR LED. Alternatively, the illuminating light emitters can be arranged in an outer periphery of the display pixels, e.g. forming a frame around the display, depending on an intensity required by a specific application, for instance. Particularly in embodiments, in which the display pixels and illuminating pixels are formed following a similar process, e.g. both elements are semiconductor devices such as micro-LEDs or VCSELs, arranging display pixels and illuminating light emitters on a common substrate can be realized in a straightforward manner.

In an embodiment, the plurality of photosensitive elements is arranged on the display substrate. Arranging the photosensitive elements alongside the display pixels on a common substrate likewise results in further minimizing the overall dimensions of the display. For example, the display pixel, the photosensitive elements and the illuminating light emitters are arranged on a common substrate according to a combination of the aforementioned arrangement examples. Thus, some or all display pixels can comprise a photosensitive element and/or an illuminating light emitter.

In an embodiment, the display further comprises a detection substrate, wherein the plurality of photosensitive elements is arranged on the detection substrate. Particularly in embodiments, in which the photosensitive elements are of a different technology as the display pixels, an arrangement on different substrates may be necessary for fabrication purposes. For example, the photosensitive elements are organic photodiodes while the display pixels and illuminating light emitters are semiconductor based such as micro LEDs and VCSELs. Alternatively, the illuminating light emitters can be arranged alongside the photosensitive elements on the detection substrate.

In an embodiment, the plurality of display pixels form an OLED display, a micro-LED display or a liquid crystal display, LCD. The displaying elements of the transparent display with capturing capability can be formed from existing technologies already employed in transparent displays such as OLEDs or LCDs. Particularly micro LEDs can further serve to increase a transparency of the display due to their small footprint. Likewise, the illuminating light emitters can be formed accordingly on based on a different technology based on a requirement of the application and what kind of application is best suited.

In an embodiment, the photosensitive elements are silicon-based photodiodes or organic photodetectors or photodiodes, OPDs. Like the display pixels, the photosensitive elements can be manufactured according to different technologies and thus tailored to a specific application in terms of sensitivity, power consumption and size, for instance. Therein, organic photodiodes are characterized by a lower power consumption compared to their semiconductor counterparts. Thus, the photosensitive elements can be silicon photodiodes for a targeted sensitivity in the NIR range.

In an embodiment, the display further comprises an optics substrate, wherein the optical modulator is arranged on the optics substrate. The optical modulator is arranged in close proximity of the imaging sensor portion. Thus, the optics substrate can be arranged immediately adjacent to a substrate that comprises the photosensitive elements. Alternatively, a spacer, or even the display substrate, can be arranged in between a detection substrate and the optics substrate. For example, the transparent display comprises exactly two substrates, wherein a first substrate includes the display pixels, photosensitive elements and the illuminating light emitters, and a second substrate includes the optical modulator.

In an embodiment, the optical modulator is an active matrix that is based on one of: liquid crystals, optical switches, and other types of spatial and digital light processors. The transparent display in these embodiments can further comprise a controller for controlling elements of the active matrix. Dynamic and programmable modulators, also referred to as spatial light modulators, can be used as an alternative to fixed masks. For example, the active matrix is based on liquid crystal technology, which can be used for programmable amplitude modulation. For programmable phase modulation, LC on silica devices can be employed in the active matrix. Further examples include vanadium oxide transistors acting as optical switches in the NIR region while being transmissive at visible frequencies. Programmable modulators have the advantage that a mask pattern can be easily and quickly changed such that multiple images, each with different optical encoding, can be captured in a subsequent manner. Moreover, in embodiments with a relatively small number photosensitive elements, programmable modulators can facilitate the obtainment of sufficient measurements for reconstruction. Also, in case of a sensor array of photosensitive elements, the ability to change the modulation pattern between acquisitions provides an extra degree of freedom that can further improve a reconstruction performance or a resolution of the reconstructed image. However, an active matrix requires additional components such as the aforementioned controller as well as being characterized by an additional power consumption channel.

In an embodiment, the optical modulator is a passive matrix that is based on one of: an amplitude mask, a phase mask, and a plurality of diffractive elements. Alternatively to an active matrix, the optical modulation can be performed passively using amplitude masks, diffractive masks, random reflective surfaces and modified microlens arrays. Therein, amplitude modulators comprise transparent and occluding regions arranged in some fixed spatial pattern on a 2D mask. Phase modulators, on the other hand, alter the relative optical path length or effective phase retardation in a 2D pattern. Phase masks can be more light efficient due to non-existent or negligible attenuation of the incoming light, and they can concentrate light to create sharper and higher-contrast patterns on the image sensor, thus also improving the image reconstruction performance.

In an embodiment, the optical modulator is realized by a spatially distributed plurality of pinholes. An amplitude mask passes, blocks, or attenuates incident light. One of the simplest architectures of a binary amplitude mask is a distribution of pinholes. Amplitude masks typically have the advantage of being easier to fabricate for a wide range of wavelengths. Outside the visible range, materials that can block light are easier and cheaper to find than those that can refract light, for instance. In particular, materials transmissive in the visible range and opaque in the NIR or SWIR range can be easily formed into an optical modulator mask. For example, dye-based polymers such as the Fujifilm SIR850W, SIR850N, or SIR940 can be applied to form the amplitude masks. These polymers show a narrow band of absorption in the infrared band between 850 and 940 nm, while maintaining a high transparency in the visible range. Their thickness ranges from 0.8 to 1.36 μm. A further example of an optical modulator suitable for lensless imaging is a diffusor. Besides an amplitude modulation, the interaction of light with the pinholes can be based on modulation of an incoming light phase or polarization. To this end, phase-shifting materials can be used in the range of the illumination wavelength as long as they are transparent in the visible range.

In an embodiment, the optical modulator forms a coded aperture mask, in particular characterized by a uniformly redundant array, URA, or an optimized random pattern, ORA. For computational imaging purposes, the optical modulator of the lensless system can be a regular pattern such as uniformly redundant arrays, URA, and random (or pseudo-random) M-sequences. In lensless imaging, coded apertures or coded-aperture masks are grids, gratings, or other patterns of materials opaque to various wavelengths of electromagnetic radiation, i.e. the illuminating wavelength range. By blocking radiation in a known pattern, a coded shadow is cast upon a plane. The properties of the original radiation sources can then be mathematically reconstructed from this shadow using an algorithm that includes knowledge about the mask pattern. Examples include Fresnel zone plates, optimized random patterns, URAs as well as hexagonal or modified URAs. The concept of coded aperture imaging itself is a well-known concept particularly in X- and gamma ray imaging systems, in which the rays cannot be focused with lenses or mirrors designed for visible light.

In an embodiment, the substantial transparency of the display in the visible domain is realized by a distributed arrangement of the display pixels and the photosensitive elements with voids in between, such that a substantial amount of electromagnetic radiation in the visible domain incident on the display is transmitted. As mentioned above, the optical elements can be arranged such that at least 70% of the light intensity in the visible domain is transmitted through the display. Therefore, the display pixels, photosensitive elements and illuminating light emitters are spaced distant from each other such that voids in between allow for visible light to be transmitted. Therein, the substrates employed are likewise transparent at visible wavelengths. Moreover, the optical modulator affects light at the illumination wavelength range, however, not at visible frequencies.

Moreover, a transparent imaging system is provided, which comprises a transparent display according to one of the aforementioned embodiments of the transparent display, and a processing unit coupled to the display and configured to reconstruct an image by applying an algorithm to the photo signals. The transparent imaging system can be an integrated system, in which the processing unit is embedded within the display. Alternatively, the processing unit can be an external component that is coupled to active elements of the transparent display. The processing unit can further be employed to synchronize an illumination of the scene or the object by means of activating and deactivating an emission of the illuminating light emitters with an active detection, i.e. an integration time, of the photosensitive elements. For reconstruction, the processing unit is configured to apply an algorithm to the photo signals, wherein the algorithm takes into account a property of the optical modulator, e.g. a layout or pattern of a coded aperture mask. Depending on the application, the algorithm can be used to reconstruct the image of the scene, e.g. via deconvolution or deep neural networks, or perform a specific recognition task, e.g. face identification, or feature-extraction from the raw sensor image.

In an embodiment, the processing unit is further configured to control the generation of the display image based on the reconstructed image. For example, the information to be displayed on the transparent display can depend on information identified in the captured and reconstructed image. To this end, the processing unit can be configured to identify objects in the reconstructed image, e.g. road signs, and display content that relates to this object on the display, e.g. driving or walking instructions.

Moreover, an electronic device is provided, which comprises a transparent display or a transparent imaging system according to one of the aforementioned embodiments. The electronic device can be a wearable device such as smart glasses. Alternatively, the transparent display or the transparent imaging system can be employed in a transparent object, such as a vehicle's windshield, for forming a heads-up display with imaging capability that does not rely on projections. In particular, a transparent display and a transparent imaging system is employed in applications where a displaying of an image is desired, while at the same time maintaining an unobstructed line-of-sight behind the display from the user's point of view. In such devices, the display can serve as augmented reality display or for displaying data detected in the field of view of the display's image sensor and the user, e.g. recognized speed limits from road signs, for instance.

Furthermore, a method of manufacturing a transparent display with lensless imaging capability is provided. The method comprises arranging a plurality of display pixels on a display substrate, the plurality of display pixels being configured to generate a display image in the visible domain of the electromagnetic spectrum, and providing a plurality of light emitters configured to illuminate a scene or an object with electromagnetic radiation within an illumination wavelength range that is outside the visible domain. The method further comprises providing a plurality of photosensitive elements configured to capture electromagnetic radiation received from the scene or the object within the illumination wavelength range and to generate photo signals depending on the captured electromagnetic radiation, and providing an optical modulator arranged on an incident side of the plurality of photosensitive elements and configured to transmit electromagnetic radiation in the visible domain, and to modulate electromagnetic radiation within the illumination wavelength range. Therein, the display is substantially transparent in the visible domain.

Further embodiments of the method become apparent to the skilled reader from the aforementioned embodiments of the transparent display, the imaging system, and the electronic device, and vice-versa.

The following description of figures may further illustrate and explain aspects of the transparent display, the imaging system and the method of manufacturing a transparent display. Components and parts of the transparent display that are functionally identical or have an identical effect are denoted by identical reference symbols. Identical or effectively identical components and parts might be described only with respect to the figures where they occur first. Their description is not necessarily repeated in successive figures.

In the figures:

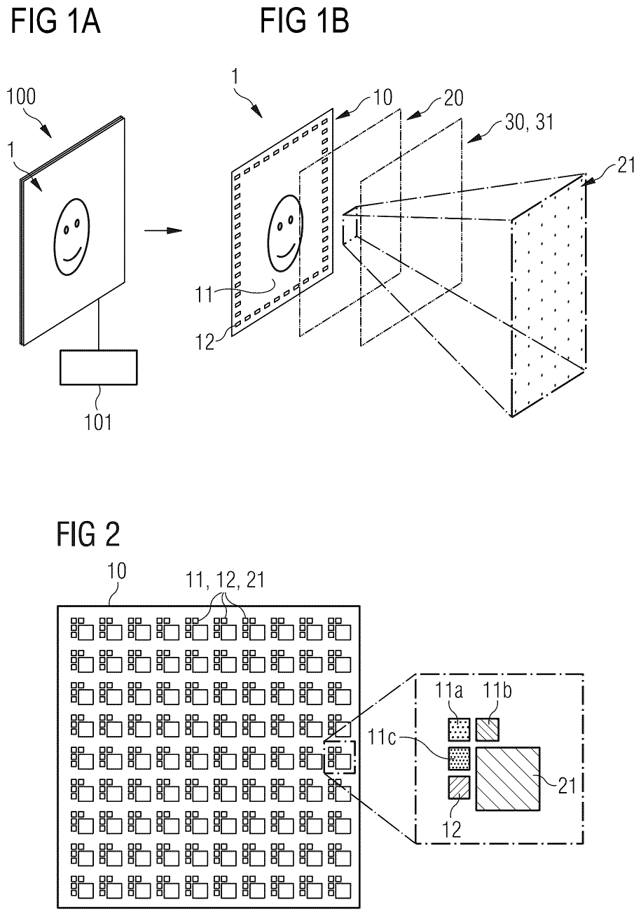

FIG. 1 shows an exemplary embodiment of a transparent imaging system comprising a transparent display according to the improved concept;

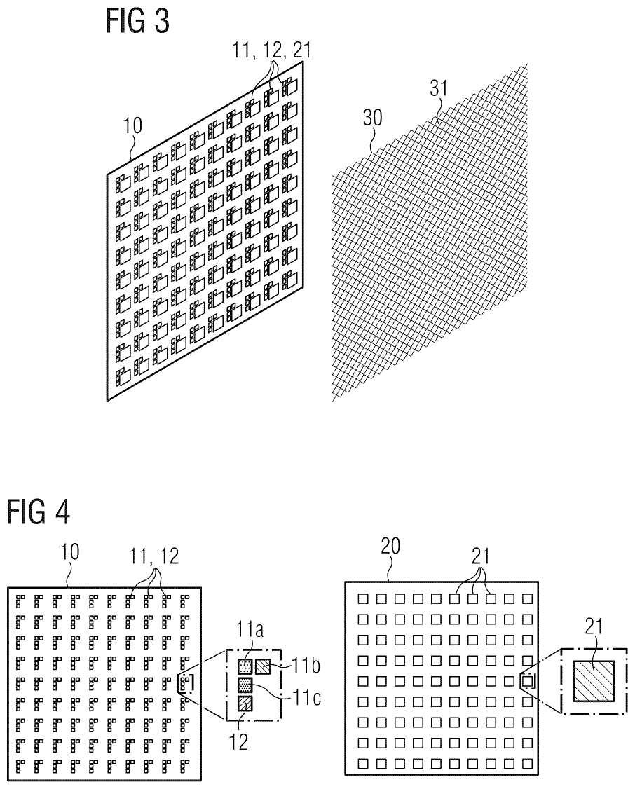

FIGS. 2 and 3 show aspects of a first exemplary embodiment of a transparent display with lensless imaging capability;

FIGS. 4 and 5 show aspects of a second exemplary embodiment of a transparent display with lensless imaging capability;

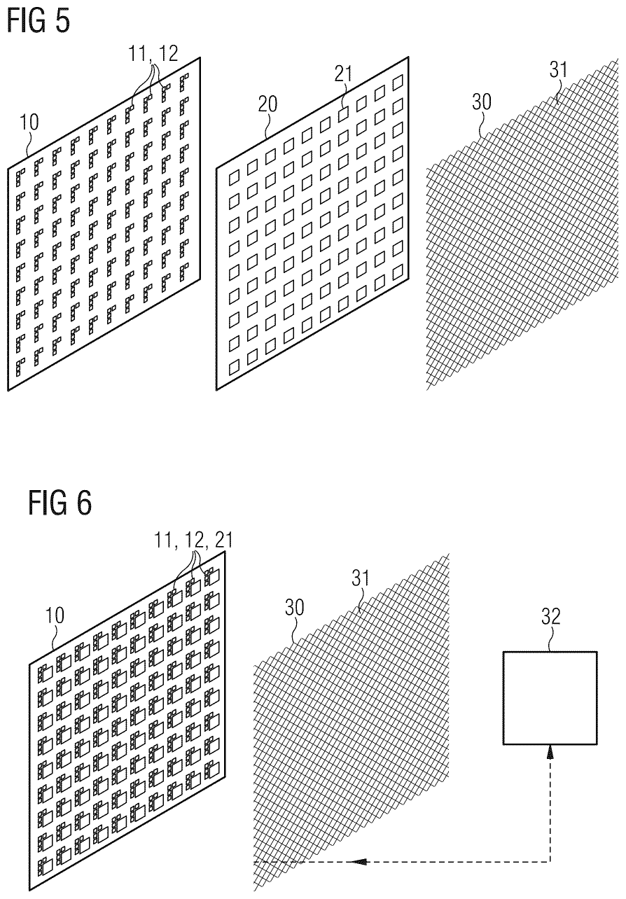

FIG. 6 shows a third exemplary embodiment of a transparent display with lensless imaging capability; and

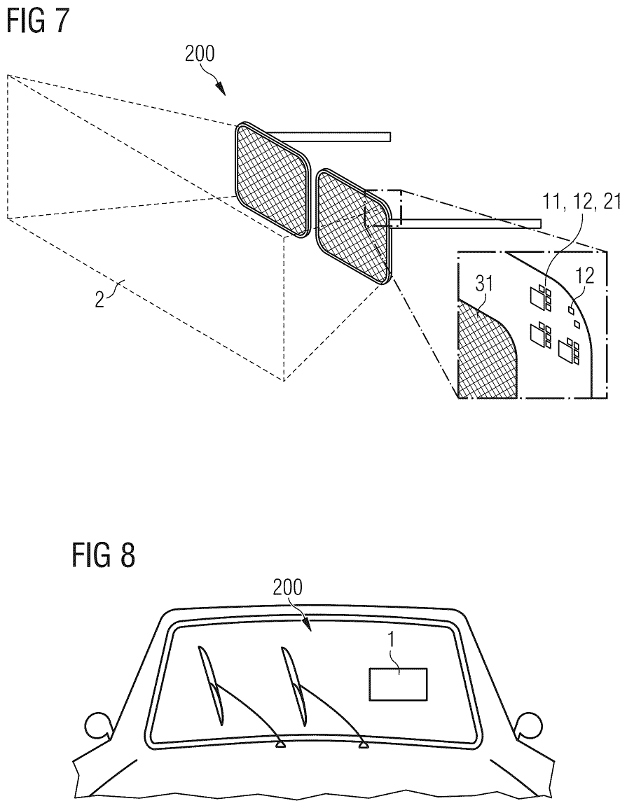

FIGS. 7 and 8 show embodiments of an electronic device and a vehicle's windshield comprising an imaging system.

FIG. 1 in panel (a) shows an exemplary embodiment of a transparent imaging system 100 comprising a transparent display 1 according to the improved concept. The imaging system 100 further comprises a processing unit 101 that is electrically coupled to the transparent display 1, e.g. to an integrated circuit of the transparent display 1. The processing unit 101 is configured to control an illumination of a scene or an object 2 by means of the illuminating light emitters 12 and a capturing by means of an image sensor formed by the photosensitive elements 21. For example, the processing unit 101 synchronizes the illumination and the imaging process. The processing unit 101 is further configured to reconstruct an image from the photo signals received from each of the photosensitive elements 21 by means of applying an algorithm. Depending on the application, the algorithm can be used to reconstruct an image of the scene via deconvolution or deep neural networks or perform a specific recognition task, e.g. face identification, or feature-extraction from the raw sensor image. The processing unit 101 can further be configured to control an image that is displayed on the transparent display 1 via controlling an emission of the display pixels 11. For example, the displayed image depends on the reconstructed image or on features recognized in the reconstructed image.

FIG. 1 in panel (b) shows an exploded view of an exemplary embodiment of a transparent display 1 according to the improved concept. The transparent display 1 comprises a display substrate 10, on which the display pixels 11 and the illuminating light emitters 12 are arranged. The display substrate 10 is transparent in the visible range of the electromagnetic spectrum, e.g. at optical wavelengths between 400 and 750 nm. For example, the display substrate 10 is a foil, a thin film, a silica or a glass substrate. The display pixels 11 are arranged in a two-dimensional matrix arrangement such that a display is formed for displaying an image in the visible domain. Moreover, in this embodiment the illuminating light emitters 12 are arranged in an outer periphery of the display pixels 11 and are configured to illuminate a scene or an object 2 with light outside the visible domain. For example, the illuminating light emitters 12 are configured to emit light in the NIR or SWIR domain. The display pixels 11 and the illuminating light emitters 12 can be formed from liquid crystal pixels, micro-LEDs, OLEDs or VCSELs, for instance. Therein, the optical elements forming the display pixels 11 and the illuminating light emitters 12 are arranged in a distributed manner having voids in between each other such that the display substrate 10 together with the pixels 11 and emitters 12 appear transparent to a user.

The transparent display 1 further comprises a detection substrate 20, on which the photosensitive elements 21 are arranged. Like the display pixels 11, the photosensitive elements can be arranged in a two-dimensional matrix arrangement such that an image sensor for capturing an image is formed. Therein, the matrix arrangement of the photosensitive elements 21 can be of similar or equal dimensions as that of the display pixels 11, or smaller as illustrated in this exemplary embodiment, in which the photosensitive area is limited to a central portion of the total surface. For example, the photosensitive elements 21 are semiconductor photodiodes, such as silicon-based photodiodes particular for imaging in the NIR regime, or organic photodiodes, OPDs. The photosensitive elements on their incident side can comprise a coating or a filter element for blocking visible light. For example, the photosensitive elements are sensitive to a small wavelength range including the illumination wavelength range of the light emitters 12, e.g. the NIR or SWIR domain. Like the display substrate 10, the detection substrate 20 is transparent in the visible range of the electromagnetic spectrum and can be formed from a foil, a thin film, a silica or a glass substrate.

The transparent display 1 further comprises an optics substrate 30, on which the optical modulator 31 is arranged. The optical modulator 31 realizes an optical encoder for lensless imaging. For example, the optical modulator 31 is a passive modulator and is realized by an amplitude mask, a phase mask, or a plurality of diffractive elements. Examples include an arrangement of pinholes, a diffusor, a Fresnel zone plate, and coded aperture masks characterized by a uniformly redundant array or an optimized random pattern, for instance. The optical modulator 31 is engineered to only manipulate light at or around the illumination range, e.g. the NIR or SWIR domain, however, for light in the visible domain, the optical modulator 31 is transparent.

The layers formed from the display substrate 10, the detection substrate 20 and the optics substrate 30 are arranged in a stacked manner, optionally with spacers in between, to form the finalized transparent display with lensless imaging capability as depicted in panel (a). The transparent display 1 can comprise further transparent layers, e.g. a transparent circuit substrate comprising active and passive circuitry for operating the display 1.

FIG. 2 shows the display substrate 10 of a first exemplary embodiment of a transparent display 1 with lensless imaging capability. Therein, the display substrate 10 comprises the aforementioned matrix arrangement of the display pixels 11 that are formed by subpixels 11a, 11b, 11c for emitting light in different subdomains of the visible spectrum. For example, the subpixels 11a, 11b, 11c are formed from red, green and blue emitting diodes, respectively, wherein the diodes can be micro-LEDs for instance. In this embodiment, each pixel 11 further comprises an illuminating light emitter 12, e.g. a NIR emitting micro-LED, and a photosensitive element 21, e.g. a silicon-based micro photodiode. Alternatively, the subpixels 11a, 11b, 11c, the illuminating light emitter 12, and the photosensitive element 21 are organic diodes. Moreover, alternatively to each pixel 11 of the display 1 comprising a light emitter 12 and a photosensitive element 21, only some pixels can comprise a photosensitive element 21, e.g. pixels 11 arranged in a center portion of the display 1, and only some pixels 11 can comprise an illuminating light emitter 12, e.g. pixels 12 situated in an outer periphery of the display 1.

FIG. 3 shows an exploded view of the first exemplary embodiment of a transparent display 1 comprising the display substrate 10 with the active optical elements and the optics substrate 30 with the optical modulator 31. Compared to the embodiment of FIG. 1, in this embodiment no dedicated detection substrate 20 is necessary. These embodiments hence provide a compact solution particularly in situations, in which display pixels 11, light emitters 12 and photosensitive elements 21 are based on the same technology, i.e. all elements are either semiconductor based or organic, for instance.

FIG. 4 shows the display substrate 10 of a second exemplary embodiment of a transparent display 1 with lensless imaging capability. Therein, the display substrate 10 comprises the aforementioned matrix arrangement of the display pixels 11 that are formed by subpixels 11a, 11b, 11c for emitting light in different subdomains of the visible spectrum. For example, the subpixels 11a, 11b, 11c are formed from red, green and blue emitting diodes, respectively, wherein the diodes can be micro-LEDs for instance. In this embodiment, each pixel 11 further comprises an illuminating light emitter 12, e.g. a NIR emitting micro-LED. Alternatively, the subpixels 11a, 11b, 11c as well as the illuminating light emitter 12 are organic diodes. Moreover, alternatively to each pixel 11 of the display 1 comprising a light emitter 12, only some pixels 11 can comprise an illuminating light emitter 12, e.g. pixels 12 situated in an outer periphery of the display 1.

In this second embodiment, the photosensitive elements 21 are arranged on a separate detection substrate 20. This can be beneficial if the display pixels 11 and light emitters 12 are based on a different technology than the photosensitive elements 21. For example, the elements on the display substrate are semiconductor based, while the photosensitive elements are organic or vice versa, such as a combined arrangement is not possible due to fabrication reasons. An advantage of choosing different technologies, however, can be the tailoring to specific applications as organic elements are known to have a lower power consumption compared to semi-conductor based devices at the expense of sensitivity and/or efficiency. A matrix arrangement of the photosensitive elements 21 can correspond to a matrix arrangement of the display pixels 11. However, also different arrangements in terms of numbers of rows and columns and/or spacing can be chosen. In a yet alternative embodiment, the illuminating light emitters 12 can be arranged alongside the photosensitive elements 21 on the detection substrate 20.

FIG. 5 shows an exploded view of the second exemplary embodiment of a transparent display 1 comprising the display substrate 10 with the emitting optical elements, the detection substrate 20 comprising the photosensitive elements 21 and the optics substrate 30 with the optical modulator 31 similar to the embodiment of FIG. 1.

FIG. 6 shows a third exemplary embodiment of a transparent display 1 with lensless imaging capability. Compared to the embodiment of FIG. 2, in this embodiment the optical modulator 31 is an active element, i.e. an active matrix. Hence, the display 1 further comprises a controller 32 that is electrically coupled to the optical modulator 31 for controlling elements of the active matrix. The active matrix can comprise liquid crystals, optical switches, and/or other types of spatial and digital light processors. For example, the optical modulator 31 is based on liquid crystal technology, which can be used for programmable amplitude modulation. For programmable phase modulation, LC on silica devices can be employed in the active matrix. Further examples include vanadium oxide transistors acting as optical switches in the NIR region while being transmissive at visible frequencies.

A programmable optical modulator 31 has the advantage that a mask pattern can be easily and quickly changed such that multiple images, each with different optical encoding, can be captured in a subsequent manner. Moreover, in embodiments with a relatively small number of photosensitive elements, a programmable modulator 31 can facilitate the obtainment of sufficient measurements for reconstruction. Also, in case of a sensor array of photosensitive elements, the ability to change the modulation pattern between acquisitions provides an extra degree of freedom that can further improve a reconstruction performance or a resolution of the reconstructed image. The controller 32 can be coupled to the processing unit 101 of an imaging system to be synchronized with an emission of the illuminating light emitters 12 and a detection of the photosensitive elements 21, i.e. an exposure phase.

FIG. 7 shows an embodiment of an electronic device 200 comprising an imaging system 100, in particular a transparent display 1, according to the improved concept. As illustrated in the zoomed portion of the image, a first layer, e.g. the display substrate 10, comprises the display pixels 11, e.g. formed from the aforementioned subpixels 11a, 11b, 11c, the illuminating light emitters 12 and the photosensitive elements 21 similar to the first embodiment of FIG. 2. Additionally or alternatively, the light emitters 12 can be arranged in an outer periphery as also illustrated in the figure. Therein, the transparent display 1 and the imaging system 100 realize applications requiring an unobstructed line-of-sight of a scene or an object 2 while augmenting the displayed information.

FIG. 8 illustrates an alternative application with a transparent display 1 being integrated in a car's windshield for augmenting the scene or object 2 visible to the driver and/or passengers while maintaining the absolutely essential unobstructed line-of-sight of the scene in front of the car.

The embodiments of the transparent display 1, the transparent imaging system 100 and the method of manufacturing a transparent display disclosed herein have been discussed for the purpose of familiarizing the reader with novel aspects of the idea. Although preferred embodiments have been shown and described, changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

This patent application claims the priority of German patent application DE 10 2022 113 231.5, the disclosure content of which is hereby incorporated by reference.

### REFERENCES

1 display
2 scene or object
10 display substrate
11 display pixel
11a, 11b, 11c subpixel
12 illuminating light emitter
20 detection substrate
21 photosensitive element
30 optics substrate
31 optical modulator
32 controller
100 imaging system
101 processing unit
200 electronic device

1. A transparent display with lensless imaging capability, comprising:
a plurality of display pixels arranged on a display substrate, the plurality of display pixels being configured to generate a display image in the visible domain of the electromagnetic spectrum;
a plurality of light emitters arranged on the display substrate and configured to illuminate a scene or an object with electromagnetic radiation within an illumination wavelength range that is outside the visible domain;
a plurality of photosensitive elements configured to capture electromagnetic radiation received from the scene or the object within the illumination wavelength range and to generate photo signals depending on the captured electromagnetic radiation; and
an optical modulator arranged on an incident side of the plurality of photosensitive elements and configured to transmit electromagnetic radiation in the visible domain, and to modulate electromagnetic radiation within the illumination wavelength range; and
wherein the display is substantially transparent in the visible domain.

2. The transparent display according to claim 1, wherein the illumination wavelength range is in the near-infrared, NIR, domain.

3. The transparent display according to claim 1, wherein the light emitters are OLEDs, micro-LEDs or vertical-cavity surface-emitting lasers, VCSELs.

4. The transparent display according to claim 1, wherein the plurality of photosensitive elements is arranged on the display substrate.

5. The transparent display according to claim 1, further comprising a detection substrate, wherein the plurality of photosensitive elements is arranged on the detection substrate.

6. The transparent display according to claim 1, wherein the plurality of display pixels form an OLED display, a micro-LED display or a liquid crystal display, LCD.

7. The transparent display according to claim 1, wherein the photosensitive elements are silicon-based photodiodes or organic photodetectors, OPDs.

8. The transparent display according to claim 1, further comprising an optics substrate, wherein the optical modulator is arranged on the optics substrate.

9. The transparent display according to claim 1, wherein the optical modulator is an active matrix that is based on one of: liquid crystals, optical switches, digital light processors and spatial light processors.

10. The transparent display according to claim 1, wherein the optical modulator is a passive matrix that is based on one of: an amplitude mask, a phase mask, and a plurality of diffractive elements.

11. The transparent display according to claim 1, wherein the optical modulator is realized by a spatially distributed plurality of pinholes.

12. The transparent display according claim 1, wherein the optical modulator is formed from a dye-based polymer.

13. The transparent display according to claim 1, wherein the optical modulator forms a coded aperture mask, in particular characterized by a uniformly redundant array, URA, or an optimized random pattern, ORA.

14. The transparent display according to claim 1, wherein the substantial transparency of the display in the visible domain is realized by a distributed arrangement of the display pixels and the photosensitive elements with voids in between, such that a substantial amount of electromagnetic radiation in the visible domain incident on the display is transmitted.

15. A transparent imaging system, comprising:
a transparent display according to claim 1; and
a processing unit coupled to the display and configured to reconstruct an image by applying an algorithm to the photo signals.

16. The transparent imaging system according to claim 15, wherein the processing unit is further configured to control the generation of the display image based on the reconstructed image.

17. An electronic device comprising a transparent display according to claim 1.

18. A method of manufacturing a transparent display with lensless imaging capability, the method comprising:
arranging a plurality of display pixels on a display substrate, the plurality of display pixels being configured to generate a display image in the visible domain of the electromagnetic spectrum;
providing a plurality of light emitters configured to illuminate a scene or an object with electromagnetic radiation within an illumination wavelength range that is outside the visible domain, wherein the plurality of light emitters is arranged on the display substrate;
providing a plurality of photosensitive elements configured to capture electromagnetic radiation received from the scene or the object within the illumination wavelength range and to generate photo signals depending on the captured electromagnetic radiation; and
providing an optical modulator arranged on an incident side of the plurality of photosensitive elements and configured to transmit electromagnetic radiation in the visible domain, and to modulate electromagnetic radiation within the illumination wavelength range; and
wherein the display is substantially transparent in the visible domain.

19. An electronic device comprising a transparent imaging system according to claim 15.

20. An electronic device comprising a transparent imaging system according to claim 16.
